(19) United States
(12) Patent Application Publication
(10) Pub. No.: US 2006/0084219 A1
(43) Pub. Date: Apr. 20, 2006

(54) Advanced NROM structure and method of fabrication

(75) Inventors: Eli Lusky, Tel-Aviv (IL); Assaf Shappir, Kiryat Ono (IL); Ilan Bloom, Haifa (IL); Boaz Eitan, Ra'anana (IL)

Correspondence Address: TIAJOLOFF & KELLY, CHRYSLER BUILDING, 37TH FLOOR, 405 LEXINGTON AVENUE, NEW YORK, NY, 10174, US

(73) Assignee: Saifun Semiconductors, Ltd., Netanya (IL)

(21) Appl. No.: 11/247,733

(22) Filed: Oct. 11, 2005

Related U.S. Application Data
(60) Provisional application No. 60/618,165, filed on Oct. 14, 2004.

(51) Int. Cl. H01L 21/8238; H01L 21/3205

(52) U.S. Cl. 438/201; 438/786; 438/587

(57) ABSTRACT

A method for creating a non-volatile memory array includes generating polysilicon columns on top of an oxide-nitride-oxide (ONO) layer, creating spacing elements on the sides of the polysilicon columns, implanting bit lines into the substrate at least between the spacing elements, depositing oxide filler over the bit lines, depositing a second polysilicon layer over the array and etching the second polysilicon layer into word lines and the polysilicon columns between the word lines.

### CROSS-REFERENCE TO RELATED APPLICATIONS

This application claims benefit from U.S. Provisional Patent Application No. 60/618,165, filed Oct. 14, 2004, which application is hereby incorporated by reference.

### FIELD OF THE INVENTION

The present invention relates to nitride read only memory (NROM) cells generally and to a method of fabrication thereof in particular.

### BACKGROUND OF THE INVENTION

Dual bit memory cells are also known in the art. One such memory cell is the NROM (nitride read only memory) cell 10, shown in FIG. 1A to which reference is now made, which stores two bits 12 and 14 in a nitride based layer 16, such as an oxide-nitride-oxide (ONO) stack, sandwiched between a polysilicon word line 18 and a channel 20. Channel 20 is defined by buried bit line diffusions 22 on each side which are isolated from word line 18 by a thermally grown oxide layer 26, grown after bit lines 22 are implanted. During oxide growth, bit lines 22 may diffuse sideways, expanding from the implantation area.

NROM cells are described in many patents, for example in U.S. Pat. No. 6,649,972, assigned to the common assignees of the present invention, whose disclosure is incorporated herein. As shown in FIG. 1B, to which reference is now briefly made, NROM technology employs a virtual-ground array architecture with a dense crisscrossing of word lines 18 and bit lines 22. Word lines 18 and bit lines 22 optimally can allow a 4F² size cell, where F designates the design rule (i.e. minimum size of an element) of the technology in which the array was constructed. For example, the design rule for a 0.5 μm technology is F=0.5 μm. However, most NROM technologies which use the more advanced processes of less than 170 nm employ a larger cell, of 5-6F² due to the side diffusion of the bit lines.

A common problem is the integrity of bit line oxides 26. As can be seen in FIG. 1A, they are thick in a middle 25 but shrink to an “oxide beak” 27 at the sides. In general, middles 25 are of good quality but beaks 27 are of poor quality, and thus are susceptible to breakdown. Moreover, the thickness of middles 25 is sensitive to the concentration of n+ doping at the surface of bit line 22 and is thus, difficult to control. In older generation technologies, the solution to this was high temperature oxidation. However, this causes substantial thermal drive, which increases the side diffusion of bit lines 22.

Another common problem is that the NROM manufacturing process is significantly different than the periphery CMOS manufacturing process but, to create a wafer with both CMOS and NROM elements, both processes are integrated together. This affects the characterization of the CMOS transistors.

The following patents and patent applications attempt to solve these issues and to improve scaling. US 2004/0157393 to Hwang describes a manufacturing process for a non-volatile memory cell of the SONOS type which attempts to reduce or minimize the undesirable effects of small dimension components. U.S. Pat. No. 6,686,242 B2 to Willer et al. describes an NROM cell that they claim can be implemented within a 4F² area.

### SUMMARY OF THE PRESENT INVENTION

There is therefore provided, in accordance with a preferred embodiment of the present invention, a method for creating a non-volatile memory array. The method includes generating polysilicon columns on top of an oxide-nitride-oxide (ONO) layer, creating spacing elements on the sides of the polysilicon columns, implanting bit lines into the substrate at least between the spacing elements, depositing oxide filler over the bit lines, depositing a second polysilicon layer over the array and etching the second polysilicon layer into word lines and the polysilicon columns between the word lines.

Additionally, in accordance with a preferred embodiment of the present invention, the spacing elements are formed of oxide and are either spacers or liners.

Moreover, in accordance with a preferred embodiment of the present invention, the method includes implanting a pocket implant at least next to the polysilicon columns. The pocket implant can be of Boron, BF2 or Indium.

Further, in accordance with a preferred embodiment of the present invention, the non-volatile memory array is a nitride read only memory (NROM) array.

Still further, in accordance with a preferred embodiment of the present invention, the step of generating polysilicon columns includes depositing a layer of polysilicon over the array and etching the polysilicon columns with a polysilicon etch until reaching a bottom oxide layer of the ONO layer. In another embodiment, the first polysilicon etching step also comprises etching with an oxide etch to remove the bottom oxide layer and reoxidizing with a sidewall oxidation.

Moreover, in accordance with a preferred embodiment of the present invention, the method also includes implanting an anti-punchthrough implant after the last step of etching into the areas between the bit lines not covered by the word lines. The anti-punchthrough implant can be of Boron, BF2 or Indium and can be implemented as a combination of implants.

There is also provided, in accordance with a preferred embodiment of the present invention, another method including generating polysilicon columns on top of an ONO layer, depositing a sidewall oxide on the sides of the polysilicon columns (the oxide provides at least a portion of an oxide screen over the substrate between the polysilicon columns), implanting a pocket implant at least next to the polysilicon columns, creating spacing elements on the sides of the sidewall oxides, implanting bit lines through the oxide screen into the substrate, depositing oxide filler over at least a portion of the oxide screen, depositing a second polysilicon layer over the array and etching the second polysilicon layer into word lines and the polysilicon columns between the word lines.

Additionally, in accordance with a preferred embodiment of the present invention, the method includes forming one of a liner and a spacer on sides of the word lines.

Moreover, in accordance with a preferred embodiment of the present invention, the oxide screen is formed of the bottom oxide layer covered by oxide from the sidewall oxide deposition. Alternatively, the oxide screen is formed of oxide generated from the reoxidizing.

There is also provided, in accordance with a preferred embodiment of the present invention, a NROM array including word lines of second polysilicon, each row having a multiplicity of first polysilicon islands thereunder, a charge trapping dielectric at least under the polysilicon islands, columns of diffusion bit lines implanted in a semiconductor substrate generally perpendicular to the second polysilicon and generally between neighboring the polysilicon islands and oxide filler at least over the bit lines.

Additionally, in accordance with a preferred embodiment of the present invention, the array also includes oxide spacing elements at least next to the polysilicon islands near the bit lines. The oxide spacing elements can be spacers or liners.

Moreover, in accordance with a preferred embodiment of the present invention, the array may also include an anti-punchthrough implant in the areas between the bit lines not covered by the word lines.

Further, in accordance with a preferred embodiment of the present invention, the array also includes pocket implants at least next to the diffusion bit lines.

Finally, in accordance with a preferred embodiment of the present invention, the array also includes an oxide screen on a surface of the substrate above the bit lines.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1A is a schematic illustration of an NROM memory cell;

FIG. 1B is a schematic illustration of a layout of the cell of FIG. 1A;

FIGS. 2A and 2B together are a flow chart illustration of a manufacturing method for a novel memory cell;

FIGS. 3A, 3B, 3C, 3D and 3E are schematic illustrations of various stages in the method of FIG. 2, with FIG. 3E showing the novel memory cell; and

FIGS. 4A and 4B are layout illustrations for an array of the cells, useful in understanding the method of FIG. 2.

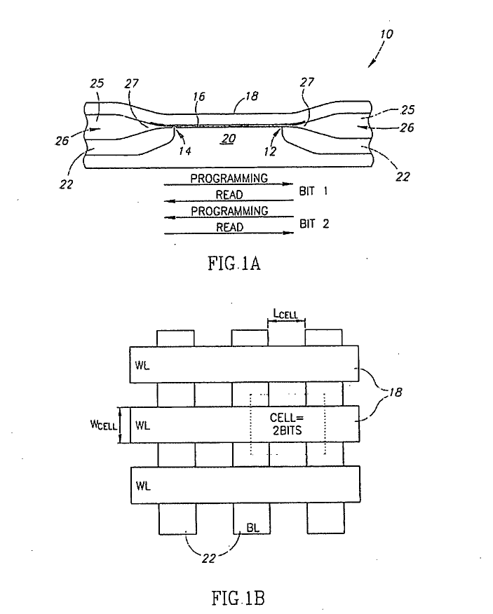

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE PRESENT INVENTION

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

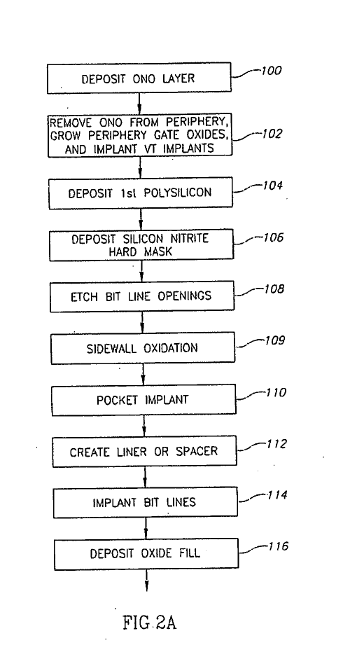

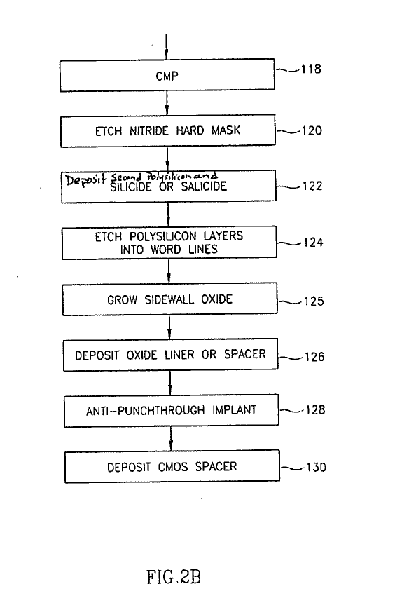

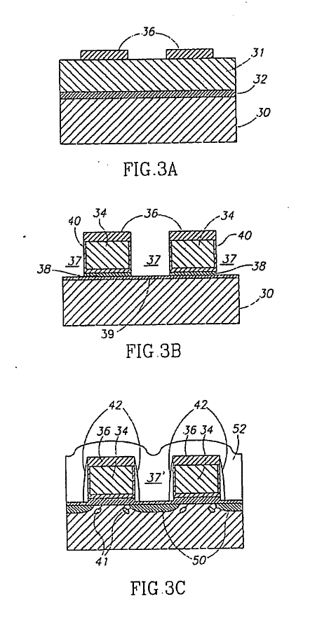

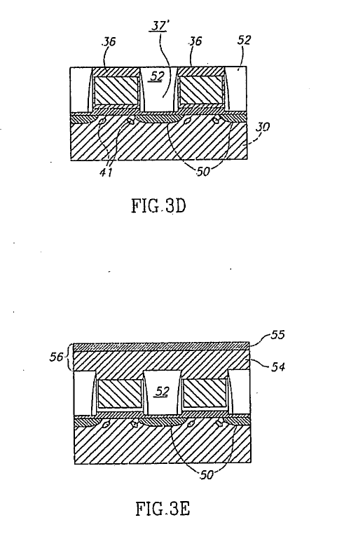

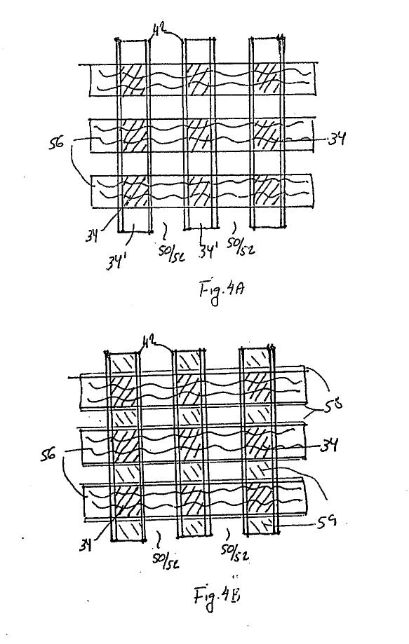

Reference is now made to FIGS. 2A and 2B, which, together, illustrate a novel process for manufacturing nitride read only memory (NROM) arrays. Reference is also made to FIGS. 3A, 3B, 3C, 3D and 3E which show the results of various steps of FIG. 2 and to FIGS. 4A and 4B which show the layout of various steps of FIG. 2.

After preparation of a substrate 30 (FIG. 3A), an ONO layer 32 may be laid down (step 100) over the entire wafer, where, in an exemplary embodiment, the bottom oxide layer may be 2-5 nm thick, the nitride layer may be 5 nm thick and the gate oxide layer may be 12-14 nm thick.

A mask may be laid down and ONO layer 32 may be removed (step 102) from the area of the chip designated for CMOS operation, after which the gate oxides of the periphery may be grown and a threshold voltage doping may be implanted for the CMOS periphery. It will be appreciated that the operations of step 102 are high thermal budget operations. Moreover, as will be seen hereinbelow, they are the last high thermal budget operations in the present process.

In step 104, a first polysilicon layer 31 may be laid down over the entire chip. A nitride hard mask 36 may then be deposited (step 106) in a column pattern covering the areas of the memory array not destined to be bit lines. FIG. 3A shows the results of step 106. Two columns of nitride hard mask 36 are shown on top of polysilicon layer 31, which overlays ONO layer 32.

An etch may be performed (step 108) to generate bit line openings 37 by removing the areas of polysilicon layer between columns of nitride hard mask layer 36. The etch may be performed in multiple ways.

In one embodiment, it is a polysilicon etch, set to over-etch by 20-50%. The over-etching may then etch away the oxide and nitride layers. For example, if the polysilicon is 70 nm thick and the over-etch is 20%, with a 4/1 poly to oxide etch rate difference, then the over-etch is 3-4 nm, which will reduce the top oxide layer (of 12-14 nm) to less than 10 nm. If the over-etch is 50%, then it may consume the entire top oxide layer and even consume part of the nitride layer. In accordance with a preferred embodiment of the present invention, the over-etch may be set to remove all but the bottom oxide layer.

In another embodiment, the etch may be performed in two steps, a first polysilicon etch to remove all but the bottom oxide layer and a second oxide etch to remove the bottom oxide. The latter may be a very short etch, to remove the 2-5 nm of the bottom oxide. Although the etch may also etch silicon substrate 30, it typically may etch only a slight amount (about 0.2-0.5 nm) and thus, may have a minimal affect on the silicon quality. This embodiment may provide a more uniform oxide thickness across the wafer. The latter may improve control of future trajectories of implants into the silicon (steps 110 and 114) and hence, better control of the overlap of the threshold and pocket implants to the bit line implant.

FIG. 3B shows the results of the etch process. Two columns 34 of first polysilicon and nitride hard mask 36 are shown on top of columns 38 of ONO layer 32. The bottom oxide, labeled 39, is shown in bit line openings 37.

Optionally, the array may now be oxidized (step 109), to create a sidewall oxide 40 to cover the now exposed polysilicon 34. An exemplary thickness may be 5 nm. The oxidation may oxidize other parts of the array, such as the bottom oxide 39 (if present) or the exposed silicon of substrate 30. For the former, bottom oxide 39 may become about 2 nm thicker. For the latter, the oxidation may react with the exposed silicon, annealing any damage due to the etching of silicon substrate 30. The latter embodiment may provide a better controlled bottom oxide 39 for implanting the bit lines, as described hereinbelow.

A pocket implant 41 (FIG. 3C), such as of Boron (BF₂), may now be implanted (step 110) next to or under polysilicon columns 34. An exemplary pocket implant may be of 1-3×10¹³/cm² at an angle of 0-15°, where the angle may be limited by the width of bit line opening 37 and the height of polysilicon columns 34 covered by nitride hard mask 36. Part of pocket implant 41 may scatter and diffuse under polysilicon columns 34. In an alternative embodiment, the pocket implant may be of Boron or Indium

In step 112, spacers 42 may be generated on the sides of polysilicon columns 34. For example, spacers 42 may be generated by deposition of an oxide liner, such as of 12 nm, and an anisotropic etch, to create the spacer shape. Alternatively, the liner may be left as it is without forming a spacer.

Spacers 42 may decrease the width of bit line openings, labeled 37′ in FIG. 3C, in order to reduce the width of the about-to-be implanted bit lines and to increase the effective length of the channels between bit lines.

Once spacers 42 have been formed, bit lines 50 may be implanted (step 114), followed by a rapid thermal anneal (RTA). In one exemplary embodiment, the bit line implant is of Arsenic of 2×10¹⁵/cm² at 10-20 Kev and with an angle of 0 or 7% to the bit line.

In step 116, an oxide filler 52 may be deposited on the chip. As can be seen in FIG. 3C, oxide filler 52 may fill reduced bit line openings 37′ and may cover other parts of the chip. In step 118, a CMP (chemical mechanical planarization) process may be performed to remove excess oxide filler 52. The result of step 118 is shown in FIG. 3D. As can be seen, the planarization may be designed to remove oxide until it reaches nitride hard mask 36.

In step 120, nitride hard mask 36 may be removed, typically via a nitride wet etch, leaving exposed openings above polysilicon elements 34. A second polysilicon layer 54 and a silicide layer 55 may then be deposited (step 122) on the entire wafer. Second polysilicon layer 54 may come into electrical contact with polysilicon elements 34 where the latter are exposed. Layers 54 and 55 may then be etched (step 124) into word lines 56 (FIG. 3E), which may be in rows perpendicular to the bit line columns. To etch the word lines, another nitride hard mask may first be deposited over the silicide layer, followed by an etch of the nitride hard mask, silicide layer 55, second polysilicon layer 54 and first polysilicon columns 34 into word lines 56. It will be appreciated that the first polysilicon is now etched into small islands in electrical contact with and self-aligned to the silicided second polysilicon word lines 56. Furthermore, word lines 56 may extend above and perpendicular to buried diffusion bit lines 50, which may be insulated from them by oxide filler 52.

In another embodiment, the step of depositing silicide layer 55 may be replaced with a salicide (self aligned silicidation) process after word line patterning.

The layout of polysilicon elements 34 and second polysilicon layer 54 may be seen more clearly in FIG. 4A. As can be seen, polysilicon elements 34 may be laid out in columns, with spacers 42 to their sides, and word lines 56 may be laid out in rows. Bit lines 50 may be implanted between spacers 42 and covered by oxide filler 52. As can be seen, when word lines 56 may be etched, portions 34′ of polysilicon elements 34 between word lines 56 may also be etched, leaving polysilicon elements 34 as islands under word lines 56.

Together, polysilicon elements 34 and word lines 56 may form the gates of each NROM cell. In addition, the polysilicon layers may form the gates, and possibly some interconnections, in the CMOS periphery.

A sidewall oxide 58 (FIG. 4B) may optionally be generated (step 125) to cover the word line surfaces that may be exposed as a result of etch step 124. An oxide liner or partial spacer, of about 10-20 in, may then be deposited (step 126), along and between word lines 56.

In step 128, an anti-punchthrough implant 59 may be generated between bit lines 50, where portions 34′ of first polysilicon elements 34 were removed. An exemplary anti-punchthrough implant may be of Boron (B) of 15 Kev at 5×10¹²/cm² or 30 Kev at 3×10¹²/cm². Alternatively, the anti-punchthrough implant may comprise a multiplicity of implants with different energies and doses in the same location. For example, there might be three consecutive implants of Boron, of 5×10¹² at 15 Kev, 3×10¹² at 25 Kev and 3×10¹² at 35 Kev. Alternatively, the Boron may be replaced by BF2 or Indium.

Finally, oxide spacers may be deposited (step 130) for the transistors CMOS periphery. The deposition may cover the entire wafer and may fill or partially fill between word lines 56, providing an insulation between word lines 56.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

What is claimed is:

1. A method for creating a non-volatile memory array, the method comprising:
generating polysilicon columns on top of an oxide-nitride-oxide (ONO) layer;
creating spacing elements on the sides of said polysilicon columns;
implanting bit lines into said substrate at least between said spacing elements;
depositing oxide filler over said bit lines;
depositing a second polysilicon layer over said array; and
etching said second polysilicon layer into word lines and said polysilicon columns between said word lines.

2. The method according to claim 1 and wherein said spacing elements are formed of oxide.

3. The method according to claim 1 and wherein said spacing elements are one of the following elements: spacers and liners.

4. The method according to claim 1 and also comprising implanting a pocket implant at least next to said polysilicon columns.

5. The method according to claim 4 and wherein said pocket implant is of one of the following materials: Boron, BF2 and Indium.

6. The method according to claim 1 and wherein said non-volatile memory array is a nitride read only memory (NROM) array.

7. The method according to claim 1 and wherein said generating polysilicon columns comprises depositing a layer of polysilicon over said array and etching said polysilicon columns with a polysilicon etch until reaching a bottom oxide layer of said ONO layer.

8. The method according to claim 7 and wherein said first polysilicon etching also comprises etching with an oxide etch to remove said bottom oxide layer and reoxidizing with a sidewall oxidation.

9. The method according to claim 1 and also comprising implanting an anti-punchthrough implant after said last step of etching into the areas between said bit lines not covered by said word lines.

10. A method for creating a non-volatile memory array, the method comprising:
generating polysilicon columns on top of an ONO layer;
depositing a sidewall oxide on the sides of said polysilicon columns, said oxide also providing at least a portion of an oxide screen over said substrate between said polysilicon columns;
implanting a pocket implant at least next to the said polysilicon columns;
creating spacing elements on the sides of said sidewall oxides;
implanting bit lines through said oxide screen into said substrate;
depositing oxide filler over at least a portion of said oxide screen;
depositing a second polysilicon layer over said array; and
etching said second polysilicon layer into word lines and said polysilicon columns between said word lines.

11. The method according to claim 10 and wherein said spacing elements are formed of oxide.

12. The method according to claim 11 and wherein said spacing elements are one of the following elements: spacers and liners.

13. The method according to claim 10 and wherein said non-volatile memory array is a nitride read only memory (NROM) array.

14. The method according to claim 10 and wherein said generating comprises depositing a layer of polysilicon over said array and etching said polysilicon columns with a polysilicon etch until reaching a bottom oxide layer of said ONO layer.

15. The method according to claim 14 and wherein said first polysilicon etching also comprises etching with an oxide etch to remove said bottom oxide layer and reoxidizing with a sidewall oxidation.

16. The method according to claim 10 and also comprising forming one of a liner and a spacer on sides of said word lines.

17. The method according to claim 16 and also comprising implanting an anti-punchthrough implant after said last step of etching into the areas between said bit lines not covered by said word lines.

18. The method according to claim 17 and wherein said anti-punchthrough implant is formed of one of the following: Boron, BF2 and Indium.

19. The method according to claim 17 and wherein the anti-punchthrough implant is a combination of implants.

20. The method according to claim 10 and wherein said oxide screen comprises said bottom oxide layer covered by oxide from said sidewall oxide deposition.

21. The method according to claim 15 and wherein said oxide screen comprises oxide generated from said reoxidizing.

22. A nitride read only memory (NROM) array comprising:
word lines of second polysilicon, each row having a multiplicity of first polysilicon islands thereunder;
charge trapping dielectric at least under said polysilicon islands;
columns of diffusion bit lines implanted in a semiconductor substrate generally perpendicular to said second polysilicon and generally between neighboring said polysilicon islands; and
oxide filler at least over said bit lines.

23. The array according to claim 22 and also comprising oxide spacing elements at least next to said polysilicon islands near said bit lines.

24. The array according to claim 23 and wherein said oxide spacing elements are one of the following elements: spacers and liners.

25. The array according to claim 22 and also comprising an anti-punchthrough implant in the areas between said bit lines not covered by said word lines.

26. The array according to claim 22 and also comprising pocket implants at least next to said diffusion bit lines.

27. The array according to claim 22 and also comprising an oxide screen on a surface of said substrate above said bit lines.
